(19) United States
(12) Patent Application Publication
(10) Pub. No.: US 2003/0039108 A1
(43) Pub. Date: Feb. 27, 2003

(54) Distribution frame having angled equipment housings and interbay storage unit

(76) Inventors: Mark R. Dagley, Ft. Worth, TX (US); Antwan J. Works, Lewisville, TX (US); Jon P. Segelhorst, Watauga, TX (US)

Correspondence Address: CORNING CABLE SYSTEMS LLC, P O BOX 489, HICKORY, NC, 28603, US

(21) Appl. No.: 09/938,096

(22) Filed: Aug. 23, 2001

(51) Int. Cl. H05K 5/06; H05K 5/04; H05K 5/00

(52) U.S. Cl. 361/753

(57) ABSTRACT

A distribution frame includes a plurality of vertically stacked equipment housings arranged in columns and an Interbay Storage Unit medially disposed in a center section between the columns. The Interbay Storage Unit includes a base and a plurality of storage hubs vertically spaced on the base. The housings are angled downwardly in the direction of the center section and the base of the Interbay Storage Unit includes reduced width sections between adjacent storage hubs that increase the space available between the Interbay Storage Unit and the housings for routing excess lengths of jumper cables. Fingers are laterally spaced about each storage hub and a plurality of routing guides are staggered on the housings to separate jumper cables routed between the housings to interconnect service and subscriber transmission lines adjacent the base of the distribution frame where the excess lengths of the jumper cables accumulate.

### BACKGROUND OF THE INVENTION

1. Field of the Invention

The present invention relates to a distribution frame of the type commonly utilized in a communications network. More specifically, the invention relates to a distribution frame for various communications equipment including equipment housings that are angled and an Interbay Storage Unit having a reduced width to increase the space available for routing and storing excess lengths of jumper cables on the distribution frame.

2. Background of the Invention

Distribution frames of the type commonly utilized in a communications network are constructed of a plurality of vertical frame members, referred to herein as “uprights,” and a plurality of horizontal frame members, referred to herein as “supports.” The supports join the uprights together to form an open, box-like frame for mounting communications equipment thereon and for routing jumper cables between the equipment. Typically, the height dimension of the distribution frame is substantially greater than the width dimension and the depth dimension. Thus, the distribution frame is relatively tall and narrow. The communications equipment is mounted within a plurality of equipment housings, each of which in turn is mounted to the distribution frame for organization and ease of interchangeability of the equipment. The communications equipment is mounted compactly within the equipment housing and the housings are mounted in close proximity to maximize the amount of equipment that can be mounted on the distribution frame and the space available for routing and storing jumper cables.

For example, a plurality of equipment housings having communications equipment mounted therein may be mounted to the distribution frame in a vertical stacked orientation. FIG. 1 illustrates an existing distribution frame 20 having a plurality of housings 22 (only 5 of which are shown for purposes of clarity) mounted on the distribution frame 20 in a vertical stacked orientation. Each of the housings 22 has at least one communications equipment module, panel, or the like 24 mounted within the housing 22. The communications equipment module 24 may, for example, be a connector module including a plurality of adapters 26 for receiving jumper cables 28 to interconnect incoming (e.g., service) and outgoing (e.g., subscriber) transmission lines that are terminated on the connector modules 24. The distribution frame 20 is constructed of a pair of vertically disposed uprights 21 that are joined together by a plurality of horizontally disposed supports 23 to form an open, generally rectangular equipment rack 25. The uprights 21 of equipment rack 25 are typically more than about 60 inches in height and are spaced between about 19 and about 23 inches apart. Accordingly, the equipment rack 25 is relatively tall and narrow.

Each equipment housing 22 is generally rectangular in cross section and extends between the uprights 21 substantially the entire width of the equipment rack 25. The jumper cables 28 are routed from an adapter 26 of a first connector module 24 through one or more routing guides 29 and strain relief devices (not shown) behind, underneath or alongside the housings 22 to an adapter 26 of a second connector module 24 to interconnect the service and subscriber transmission lines terminated to the adapters 26 on the connector modules 24. Because the housings 22 are stacked vertically on the equipment rack 25 in close proximity, there is very little space available for routing the jumper cables 28 between the connector modules 24 or for storing any excess lengths of the jumper cables. As a result, a need exists for a distribution frame with increased space available for routing and storing excess lengths of jumper cables on the distribution frame.

### SUMMARY OF THE INVENTION

The above objectives and advantages, as well as others, are realized and attained by the present invention. Additional features and advantages of the invention will be set forth in the written description that follows, as well as the accompanying drawings, or will be readily apparent from the description, or may be learned by practice of the invention.

In a particular embodiment, the invention is a housing for mounting communications equipment. The housing includes a generally planar upper wall having a first edge and a second edge and a generally planar lower wall substantially parallel to and spaced from the upper wall. The lower wall likewise has a first edge and a second edge. The housing further includes an outer wall extending between the first edge of the upper wall and the first edge of the lower wall such that the outer wall forms an acute angle with one of the upper wall and the lower wall and forms an obtuse angle with the other of the upper wall and the lower wall. The housing may further includes an inner wall extending between the second edge of the upper wall and the second edge of the lower wall such that the inner wall forms an acute angle with one of the upper wall and the lower wall and forms an obtuse angle with the other of the upper wall and the lower wall. At least one equipment module is mounted within the housing. Preferably, a plurality of equipment modules are mounted within the housing substantially parallel to the upper wall and the lower wall.

In another embodiment, the invention is a distribution frame of the type commonly utilized in a communications network for mounting communications equipment. The distribution frame includes a plurality of vertically disposed uprights and a plurality of horizontally disposed supports that join the uprights together to define a generally open, box-like equipment rack. The distribution frame further includes at least one housing secured to the equipment rack and at least one equipment module mounted within the housing. Preferably, the distribution frame includes a plurality of housings stacked vertically in a pair of parallel, spaced apart columns that define a center section therebetween and a plurality of equipment modules are mounted within each housing. Equipment modules in one of the housings of each of the columns are connected by a single length jumper cable that is routed between the equipment modules such that the excess length of the jumper cable is stored within the center section.

In another embodiment, the invention is an Interbay Storage Unit for routing and storing jumper cables on a distribution frame in a communications network. The Interbay Storage Unit includes a vertically disposed base and a plurality of storage hubs vertically spaced apart and extending outwardly from the base. The base has at least one reduced width section disposed between adjacent storage hubs. Preferably, the Interbay Storage Unit includes a plurality of pairs of storage hubs and the base has a reduced width section disposed between each pair of storage hubs. Each of the storage hubs is medially disposed between a pair of laterally spaced apart fingers extending outwardly from the base. The Interbay Storage Unit may further include a first section and a second section wherein the fingers of the first section are laterally spaced apart a greater distance than the fingers of the second section.

In another embodiment, the invention is a distribution frame of the type commonly utilized in a communications network for mounting communications equipment. The distribution frame includes a plurality of vertically disposed uprights and a plurality of horizontally disposed supports that join the uprights together to define a generally open, box-like equipment rack. The distribution frame further includes an Interbay Storage Unit medially disposed between the uprights and secured to the equipment rack. The Interbay Storage Unit includes a vertically disposed base and a plurality of storage hubs vertically spaced apart and extending outwardly from the base. The base of the Interbay Storage Unit has at least one reduced width section disposed between adjacent storage hubs.

In yet another embodiment, the invention is a distribution frame of the type commonly utilized in a communications network for mounting communications equipment. The distribution frame includes a plurality of vertically disposed uprights and a plurality of horizontally disposed supports that join the uprights together to define a generally open, box-like equipment rack. The distribution frame further includes at least one housing secured to the equipment rack and at least one equipment module mounted within the housing. Preferably, the distribution frame includes a plurality of housings stacked vertically in a pair of parallel, spaced apart columns that define a center section therebetween and a plurality of equipment modules mounted within each housing. The distribution frame further includes an Interbay Storage Unit disposed medially between the columns of housings and secured to the equipment rack. Equipment modules of one of the housings of each of the columns are connected by a single length jumper cable such that the excess length of the jumper cable is routed and stored within the Interbay Storage Unit. The distribution frame may further include a plurality of routing guides attached to the housings and arranged in a staggered orientation from the rear of the distribution frame to the front of the distribution frame.

### BRIEF DESCRIPTION OF THE DRAWINGS

The accompanying drawings, which are incorporated in and constitute a part of this specification, illustrate one or more embodiments of the invention described more fully below and together with the following detailed description, serve to further explain the invention. More specifically, in the drawings:

FIG. 1 is a perspective view of a prior art distribution frame having a plurality of equipment housings mounted thereon in vertical stacked orientation;

FIG. 2 is a perspective view of a distribution frame constructed in accordance with the invention;

FIG. 3 is a front view of the upper portion of the distribution frame of FIG. 2;

FIG. 4 is a side view of the upper portion of the distribution frame of FIG. 2;

FIG. 5 is a rear view of the upper portion of the distribution frame of FIG. 2;

FIG. 6 is a top view of the distribution frame of FIG. 2;

FIG. 7 is a perspective view of a typical equipment housing constructed in accordance with the invention for mounting on the distribution frame of FIG. 2;

FIG. 8 is a perspective view of an Interbay Storage Unit constructed in accordance with the invention for mounting on the distribution frame of FIG. 2;

FIG. 9 is a front view of the Interbay Storage Unit of FIG. 8;

FIG. 10 is a side view of the Interbay Storage Unit of FIG. 8;

FIG. 11 is a front view of the distribution frame of FIG. 2 showing the Interbay Storage Unit of FIG. 8 and a plurality of the equipment housings of FIG. 7 mounted on the distribution frame with a plurality of equipment modules mounted within each of the housings; and

FIG. 12 is a vertical sectional view of the distribution frame of FIG. 11 showing a plurality of routing guides for routing jumper cables between the equipment modules mounted within the equipment housings on the distribution frame.

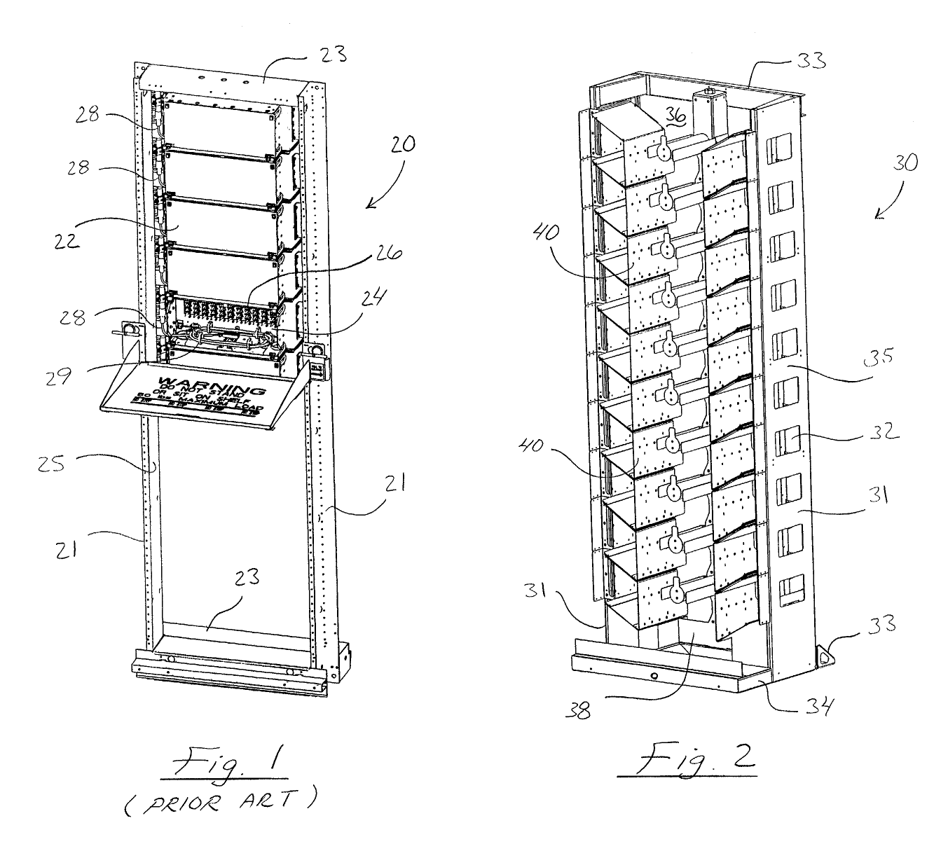

### DETAILED DESCRIPTION OF THE INVENTION

One or more embodiments of the invention will be described hereinafter in sufficient detail to permit one of ordinary skill in the art to make, use and practice the invention without undue experimentation. The embodiments shown and described herein are exemplary only and are not intended to limit the scope of the invention, as defined by the appended claims, in any manner. Instead, the invention is intended to be construed broadly with reference to this detailed description and the accompanying drawings, in which like reference numerals indicate like parts in the various views.

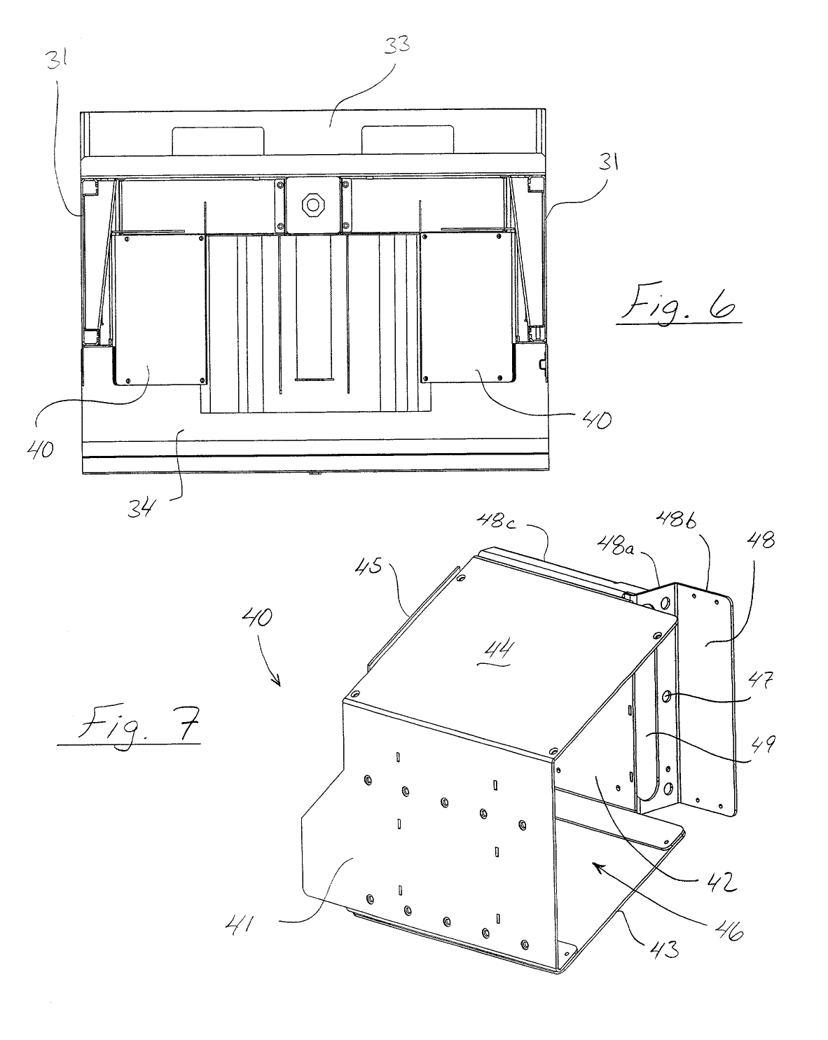

A distribution frame 30 constructed in accordance with the invention is shown in FIGS. 2-6. The distribution frame 30 comprises at least two vertically disposed upright 31 and a plurality of horizontally disposed supports 33. The uprights 31 and the supports 33 may be made of any suitable material, such as metal or rigid plastic. The supports 33 join the uprights 31 together to form an open, generally rectangular, box-like equipment rack 35 for mounting various communications equipment thereon, as will be described. The uprights 31 of equipment rack 35 are typically more than about 60 inches in height and are spaced apart a distance greater than about 23 inches. Most preferably, however, the uprights 31 are spaced apart a distance greater than about 30 inches to permit a plurality of equipment housings 40 and an Interbay Storage Unit 60 to be mounted on the distribution frame 30, as will be described. Accordingly, the equipment rack 35 is relatively tall and narrow. A plurality of openings 32 may be formed through each of the uprights 31 for aesthetics, or if necessary, to provide access to the communications equipment mounted on the equipment rack 35. The supports 33 may have any suitable construction, such as a box, C-shaped or flat beam, that provides sufficient rigidity to the equipment rack 35 when affixed to the uprights 31. As shown, the distribution frame 30 may also comprise a base 34 that extends outwardly from the uprights 31 to provide further rigidity to the equipment rack 35 in the upright, operational position.

The distribution frame 30 further comprises a plurality of equipment housings 40 mounted thereon in a vertical stacked orientation. A typical equipment housing 40 constructed in accordance with the invention is shown in greater detail in FIG. 7. The equipment housings 40 are arranged in parallel columns adjacent the uprights 31 of the distribution frame 30 and are spaced apart sufficiently so that a central cavity 36 is formed therebetween. The central cavity 36 defines a center section 38 for a purpose to be described. Housing 40 comprises an inner wall 41, an outer wall 42, a lower wall 43, an upper wall 44 and a rear wall 45. Together, the inner wall 41, the outer wall 42, the lower wall 43, the upper wall 44 and the rear wall 45 define a cavity 46 such that the housing 40 is generally box-shaped and open towards the front. A mounting flange 48 is attached to and extends outwardly from the outer wall 42. The mounting flange 48 has a first portion 48a that is generally perpendicular to the outer wall 42 and a second portion 48b that is generally parallel to the outer wall 42. The first portion 48a has a plurality of holes 47 and an elongate opening 49 formed therethrough. Each of the equipment housings 40 is secured to one of the uprights 31 by a plurality of fasteners (not shown) that extend through the openings 47 of the first portion 48a of the mounting flange 48. Alternatively, or in addition, the housing 40 may be secured to the upright 31 in any other suitable manner. For example, the housing may be secured by fasteners through openings formed in the outer wall 42, or by interlocking a channel (not shown) provided on the upright 31 with a bracket 48c fixed to the outer wall 42 of the housing 40.

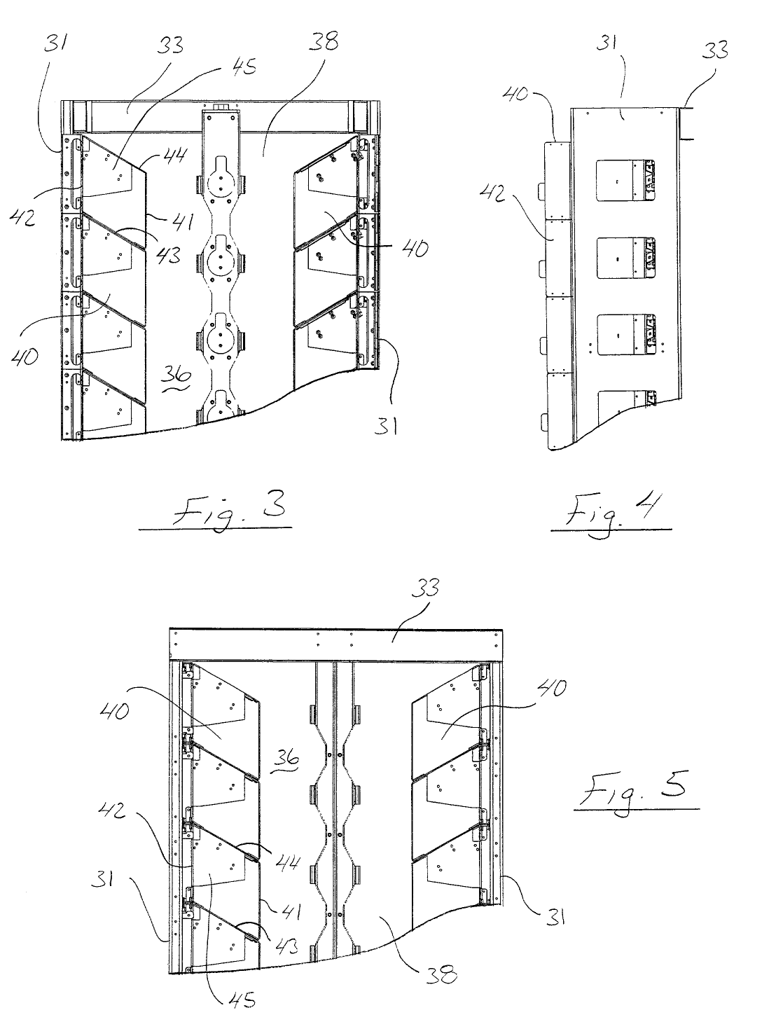

Inner wall 41 and outer wall 42 are parallel to one another and extend vertically between lower wall 43 and upper wall 44. Similarly, lower wall 43 and upper wall 44 are parallel to one another and extend laterally between inner wall 41 and outer wall 42. However, inner wall 41 and outer wall 42 are not perpendicular to lower wall 43 and upper wall 44. Together, the walls 41, 42, 43, 44 form a non-rectangular parallelogram that defines an open, box-like equipment housing 40 for mounting various communications equipment. The rear wall 45 may be included to provide additional rigidity or additional surface area for mounting the communications equipment or strain relief brackets. As best shown in FIG. 3, the lower wall 43 and the upper wall 44 are angled downwardly in the direction of the center section 38 from the outer wall 42 to the inner wall 41 when the equipment housing 40 is mounted to the upright 31 of the equipment rack 35. As a result, additional space is available within the center section 38 between the housings 40 mounted on the uprights 31 of the equipment rack 35 for routing and storing jumper cables.

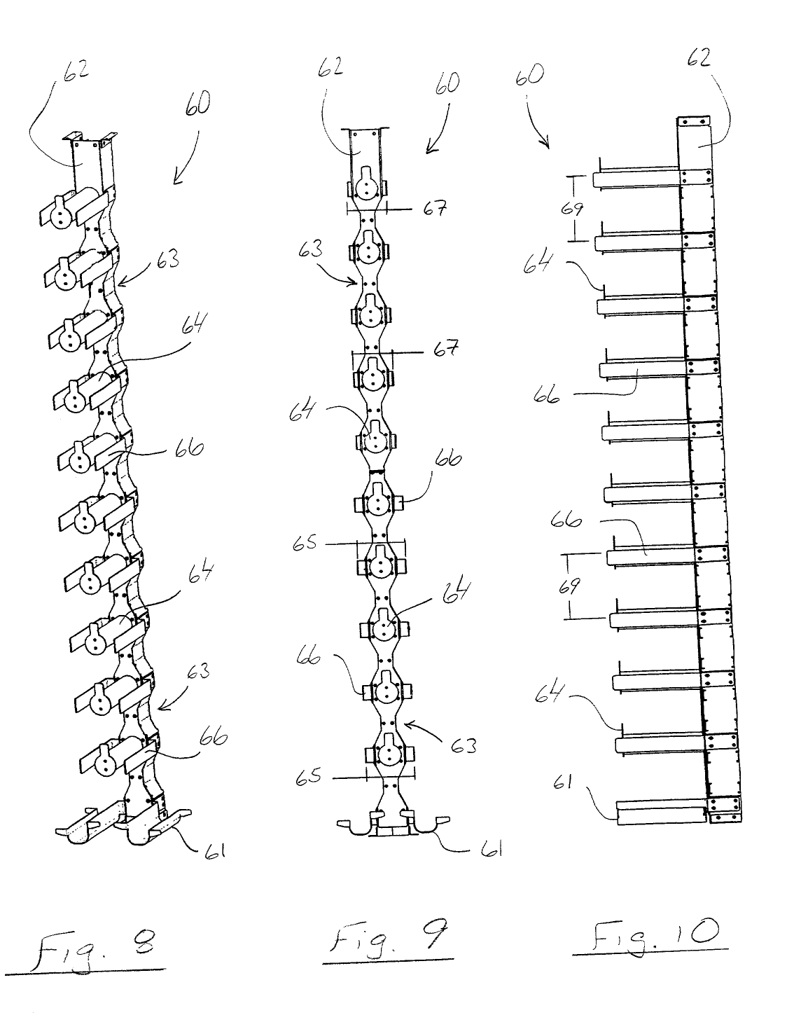

The distribution frame 30 further comprises an Interbay Storage Unit 60 mounted thereon in a vertical orientation. An Interbay Storage Unit 60 constructed in accordance with the invention is shown in greater detail in FIGS. 8-10. The Interbay Storage Unit 60 is mounted medially within the center section 38 of the distribution frame 30 between the vertical columns of housings 40, and preferably, is mounted within the center section 38 equidistant from the housings 40. The Interbay Storage Unit 60 may be secured to the equipment rack 35 in any suitable manner, for example, to a rear panel extending between the top and the bottom of the equipment rack 35, or to one or more lateral supports extending between the uprights 31 of the equipment rack 35. As shown, the Interbay Storage Unit 60 is secured to the support 33 adjacent the top of the equipment rack 35 and to the base 34 adjacent the bottom of the equipment rack 35. Preferably, the Interbay Storage Unit 60 comprises a vertically disposed base 62 having a plurality of storage hubs 64 extending outwardly therefrom in a cantilevered fashion. The storage hubs 64 depend substantially perpendicular from the base 62 towards the front of the distribution frame 30. Each storage hub 64 is medially disposed between a pair of side panels, referred to herein as “fingers,” 66 that are affixed to and extend outwardly from the base 62 in a cantilevered fashion.

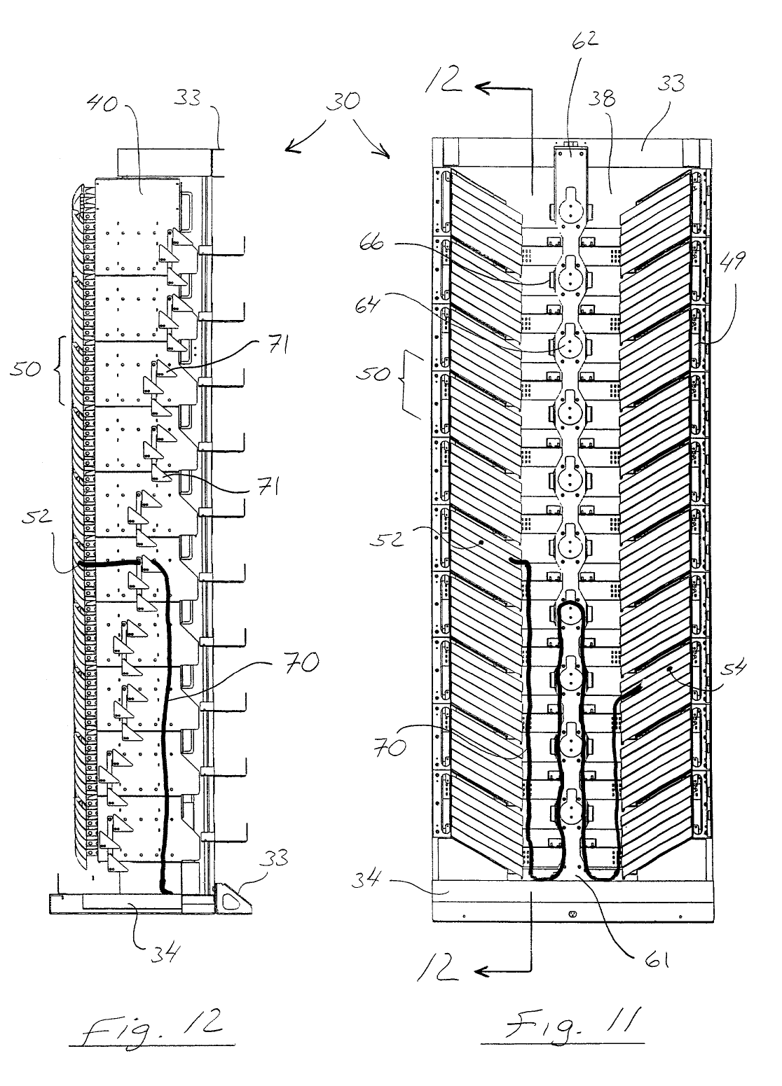

The base 62 of the Interbay Storage Unit 60 is configured to have a reduced width section 63 between each pair of adjacent storage hubs 64. As shown, the reduced width sections 63 are centrally disposed between adjacent storage hubs 64 so that the base 62 presents a “scalloped” appearance when viewed from the front or rear of the distribution frame 30. The reduced width sections 63 increase the space available between the base 62 and the inner walls 41 of the housings 40 for routing jumper cables vertically between the communication equipment within the housings 40. In addition, the reduced width sections 63 reduce the weight of the Interbay Storage Unit 60, thereby reducing the necessary cross sectional area and thickness of the uprights 31 and the supports 33. As shown, the width of the reduced width sections 63 is the same at each of the vertically spaced locations on the base 62. However, the width of the reduced width sections 63 may be further reduced so that additional space is available between the base 62 and the inner walls 41 of the housings 40 adjacent the base 34 of the distribution frame 30 where the excess lengths of single length jumper cables accumulate. The accumulation of excess lengths of jumper cables for communications equipment utilizing a single jumper cable length is commonly referred to in the art as “jumper cable pile up.” The lateral distance between each pair of fingers 66 is preferably greater near the base 34 of the distribution frame 30 to separate the jumper cables. The increased width 65 (FIG. 9) of the fingers 66 improves the ability of the Interbay Storage Unit 60 to store, separate and manage the high capacity of jumper cables in the area adjacent the base 34 of the distribution frame 30 where the excess lengths of the jumper cables accumulate. Nearer the top of the distribution frame 30, the reduced width 67 of the fingers 66 maximizes the space available in center section 38 for jumper cable management. The angled equipment housings 40 also increase the vertical distance 69 (FIG. 10) between the storage hubs 64, thereby further increasing the amount of space available in center section 38 to access, store and route jumper cables between the communications equipment mounted within the equipment housings 40. The angled housings 40 also increase the height of the reduced width sections 63, thereby maximizing the distance between the storage hubs 64 and facilitating access to the stored or routed jumper cables on the storage hubs 64 within the Interbay Storage Unit 60.

FIG. 11 illustrates an exemplary embodiment of a distribution frame 30 constructed in accordance with the invention. The distribution frame 30 comprises an Interbay Storage Unit 60 and a plurality of the equipment housings 40 of the type previously described. The Interbay Storage Unit 60 and the housings 40 are mounted on the distribution frame 30 in the manner previously described with a plurality of communications equipment modules 50 mounted within each of the housings. The communications equipment modules 50 may be any type of communications equipment, such as connector modules, panels, or the like, comprising splice organizers, splice trays, couplers or fan outs, and may be the same or different. In the exemplary embodiment shown and described herein, however, the equipment modules 50 are fiber optic connector modules including a plurality of adapters for receiving jumper cables to interconnect incoming (e.g., service) and outgoing (e.g., subscriber) transmission lines that are terminated to the adapters on the connector modules. The center section 38 of the distribution frame 30 provides space for routing connections, and in particular, single length jumper cables, between the equipment modules 50 mounted within the housings 40. As shown, six connector modules 50, each having a plurality of adapters (not shown) therein, are mounted within each of the housings 40. Accordingly, a great number of jumper cables are required to interconnect the service and subscriber transmission lines terminated to the adapters.

An example of the routing one such single length jumper cable 70 is illustrated in FIG. 11 and FIG. 12. In particular, the jumper cable 70 is routed from the front of a first connector module 52 over one or more routing guides 71 attached to the inner wall 41 of the housing 40. The jumper cable 70 is then routed downwardly to the base 34 of the distribution frame 30 and underneath a semi-cylindrical routing guide 61 attached to the base 62 of the Interbay Storage Unit 60 adjacent the base 34 of the distribution frame 30. Thereafter, the jumper cable 70 is routed upwardly between the left-hand fingers 66 and the storage hubs 64 as necessary to accommodate the excess length of the jumper cable 70. The jumper cable 70 is then routed over the appropriate storage hub 64, downwardly again to the routing guide 61, and upwardly again over one or of the routing guides 71 to the front of a second connector module 54. It should be noted by reference to FIG. 12 that the routing guides 71 transition from the rear of the distribution frame 30 towards the front of the distribution frame 30. In the exemplary embodiment shown, pairs of the routing guides 71 are staggered on inner walls 41 outwardly from a location adjacent the rear wall 45 of the housing 40 near support 33 to a location adjacent the opening of the cavity 46 of the housing 40 near the base 34 of the distribution frame 30. Staggering the locations of the routing guides 71 serves to further separate the accumulation of the jumper cables 70 adjacent the base 34 of the distribution frame 30 where jumper cable pile up tends to occur.

While the invention has been shown and described in various embodiments, it should be apparent to those skilled in the art that it is not so limited, but is susceptible to various changes without departing from the scope of invention. Accordingly, it is intended that the appended claims encompass any alternative embodiments of the invention not disclosed herein that are within the ordinary skill of a person knowledgeable in the art of distribution frames of the type commonly utilized in communications networks for interconnecting service and subscriber transmission lines and routing excess lengths of jumper cables between equipment housings mounted on the distribution frame.

That which is claimed is:

1. A housing for mounting communications equipment comprising:
a generally planar upper wall having a first edge and a second edge;
a generally planar lower wall substantially parallel to and spaced from the upper wall, the lower wall having a first edge and a second edge; and
an outer wall extending between the first edge of the upper wall and the first edge of the lower wall, the outer wall forming an acute angle with one of the upper wall and the lower wall and forming an obtuse angle with the other of the upper wall and the lower wall.

2. A housing according to claim 1 further comprising an inner wall extending between the second edge of the upper wall and the second edge of the lower wall, the inner wall forming an acute angle with one of the upper wall and the lower wall and forming an obtuse angle with the other of the upper wall and the lower wall.

3. A housing according to claim 2 wherein at least one of the outer wall and the inner wall comprises a mounting flange having a plurality of holes formed therethrough for receiving a corresponding plurality of fasteners to secure the housing to an equipment rack.

4. A housing according to claim 2 wherein the inner wall is substantially parallel to and spaced from the outer wall.

5. A housing according to claim 1 wherein at least one equipment module is mounted within the housing.

6. A housing according to claim 5 wherein a plurality of equipment modules are mounted within the housing substantially parallel to the upper wall and the lower wall.

7. A housing according to claim 1 further comprising at least one routing guide attached to the inner wall.

8. A distribution frame for mounting communications equipment comprising:
a plurality of uprights;
a plurality of supports joining the uprights together to define a generally open, box-like equipment rack; and
at least one housing secured to the equipment rack, the housing comprising
a generally planar upper wall having a first edge and a second edge;
a generally planar lower wall substantially parallel to and spaced from the upper wall, the lower wall having a first edge and a second edge; and
an outer wall extending between the first edge of the upper wall and the first edge of the lower wall, the outer wall forming an acute angle with one of the upper wall and the lower wall and forming an obtuse angle with the other of the upper wall and the lower wall.

9. A distribution frame according to claim 8 wherein the housing further comprises an inner wall extending between the second edge of the upper wall and the second edge of the lower wall, the inner wall forming an acute angle with one of the upper wall and the lower wall and forming an obtuse angle with the other of the upper wall and the lower wall.

10. A distribution frame according to claim 9 wherein the inner wall is substantially parallel to and spaced from the outer wall.

11. A housing according to claim 8 wherein at least one equipment module is mounted within the housing.

12. A housing according to claim 11 wherein a plurality of equipment modules are mounted within the housing substantially parallel to the upper wall and the lower wall.

13. A housing according to claim 8 further comprising at least one routing guide attached to the inner wall.

14. A distribution frame according to claim 8 wherein the at least one housing comprises a plurality of vertically stacked housings and wherein each of the housings comprises a plurality of equipment modules mounted within the housing such that the equipment modules are substantially parallel to one another.

15. A distribution frame according to claim 8 wherein the at least one housing comprises a plurality of housings that are stacked vertically in a pair of parallel, spaced apart columns, the columns of vertically stacked housings defining a center section therebetween for routing and storing a jumper cable between the housings.

16. A distribution frame according to claim 15 further comprising at least one equipment module mounted within at least one of the housings in each of the columns and wherein the equipment modules are connected by a single length jumper cable that is routed between the equipment modules such that the excess length of the jumper cable is stored within the center section.

17. An Interbay Storage Unit for use on a distribution frame in a communications network, the Interbay Storage Unit comprising:
a vertically disposed base; and
a plurality of storage hubs vertically spaced apart and extending outwardly from the base;
wherein the base has at least one reduced width section disposed between adjacent storage hubs.

18. An Interbay Storage Unit according to claim 17 wherein the plurality of storage hubs comprises a plurality of pairs of storage hubs and wherein the base has a reduced width section disposed between each of the pairs of storage hubs.

19. An Interbay Storage Unit according to claim 17 wherein each of the plurality of storage hubs is medially disposed between a pair of laterally spaced apart fingers extending outwardly from the base.

20. An Interbay Storage Unit according to claim 19 further comprising a first section and a second section and wherein the fingers of the first section are laterally spaced apart a greater distance than the fingers of the second section.

21. An Interbay Storage Unit according to claim 17 further comprising at least one routing to guide attached to the base.

22. A distribution frame for mounting communications equipment comprising:
a plurality of uprights;
a plurality of supports joining the uprights together to define a generally open, box-like equipment rack; and
an Interbay Storage Unit medially disposed between the uprights and secured to the equipment rack, the Interbay Storage Unit comprising
a vertically disposed base; and
a plurality of storage hubs vertically spaced apart and extending outwardly from the base;
wherein the base of the Interbay Storage Unit has at least one reduced width section disposed between adjacent storage hubs.

23. A distribution frame according to claim 22 wherein the plurality of storage hubs comprises a plurality of pairs of storage hubs and wherein the base has a reduced width section disposed between each of the pairs of storage hubs.

24. A distribution frame according to claim 22 wherein each of the plurality of storage hubs is medially disposed between a pair of laterally spaced apart fingers extending outwardly from the base.

25. A distribution frame according to claim 24 further comprising a first section and a second section and wherein the fingers of the first section are laterally spaced apart a greater distance than the fingers of the second section.

26. A distribution frame according to claim 22 further comprising at least one routing guide attached to the base.

27. A distribution frame comprising;
a plurality of uprights;
a plurality of supports joining the uprights together to define a generally open, box-like equipment rack;
at least one housing secured to the equipment rack, the housing comprising
a generally planar upper wall having a first edge and a second edge;
a generally planar lower wall substantially parallel to and spaced from the upper wall, the lower wall having a first edge and a second edge; and
an outer wall extending between the first edge of the upper wall and the first edge of the lower wall, the outer wall forming an acute angle with one of the upper wall and the lower wall and forming an obtuse angle with the other of the upper wall and the lower wall; and
an Interbay Storage Unit medially disposed between the uprights and secured to the equipment rack, the Interbay Storage Unit comprising
a vertically disposed base; and
a plurality of storage hubs vertically spaced apart and extending outwardly from the base;
wherein the base of the Interbay Storage Unit has at least one reduced width section disposed between adjacent storage hubs.

28. A distribution frame according to claim 27 wherein the housing further comprises an inner wall extending between the second edge of the upper wall and the second edge of the lower wall, the inner wall forming an acute angle with one of the upper wall and the lower wall and forming an obtuse angle with the other of the upper wall and the lower wall.

29. A distribution frame according to claim 27 wherein the at least one housing comprises a plurality of vertically stacked housings and wherein the distribution frame further comprises at least one equipment module mounted within each of the housings.

30. A distribution frame according to claim 27 wherein the at least one housing comprises a plurality of housings stacked vertically in a pair of parallel, spaced apart columns that define a center section therebetween and wherein the Interbay Storage Unit is disposed within the center section for routing and storing at least one jumper cable between the housings.

31. A distribution frame according to claim 30 further comprising at least one equipment module mounted within one of the housings of each of the columns and wherein the equipment modules are connected by a single length jumper cable such that the excess length of the jumper cable is stored within the Interbay Storage Unit.

32. A distribution frame according to claim 27 wherein the plurality of storage hubs comprises a plurality of pairs of storage hubs and wherein the base has a reduced width section disposed between each of the pairs of storage hubs.

33. A distribution frame according to claim 27 wherein each of the plurality of storage hubs is medially disposed between a pair of laterally spaced apart fingers extending outwardly from the base.

34. A distribution frame according to claim 33 further comprising a first section and a second section and wherein the fingers of the first section are laterally spaced apart a greater distance than the fingers of the second section.

35. A distribution frame according to claim 27 further comprising at least one routing guide attached to the base.

36. A distribution frame according to claim 28 wherein the at least one housing comprises a plurality of housings arranged in a vertical stacked orientation and further comprising a plurality of routing guides attached to the inner walls of the housings and arranged in a staggered orientation from the rear of the distribution frame to the front of the distribution frame.

37. A distribution frame comprising:
a plurality of uprights;
a plurality of supports joining the uprights together to define a generally open, box-like equipment rack;
at least one angled housing secured to each of the uprights of the equipment rack; and
an Interbay Storage Unit medially disposed between the uprights and secured to the equipment rack;
wherein the housings are connected by a jumper cable and the excess length of the jumper cable is routed and stored within the Interbay Storage Unit.

38. A distribution frame according to claim 37 wherein the at least one housing comprises a plurality of housings stacked vertically in a pair of parallel, spaced apart columns defining a center section therebetween and wherein the distribution frame further comprises at least one equipment module mounted within one of the housings of each of the columns, the equipment modules connected by a jumper cable routed through the center section such that the excess length of the jumper cable is stored within the Interbay Storage Unit.
